(19) United States
(12) Patent Application Publication
(10) Pub. No.: US 2009/0109582 A1
(43) Pub. Date: Apr. 30, 2009

(54) Method of protecting circuits using integrated array fuse elements and process for fabrication

(76) Inventors: Michael D. Jack, Goleta, CA (US); Michael Ray, Goleta, CA (US); Robert E. Kvaas, Goleta, CA (US); Gina M. Crawford, Goleta, CA (US)

Correspondence Address: Raytheon Company, Intellectual Property, 2000 E. EI Segundo Blvd., P.O. Box 902, EO/E04/N119, EI Segundo, CA, 90245-0902, US

(21) Appl. No.: 11/980,150

(22) Filed: Oct. 30, 2007

(51) Int. Cl. H02H 9/00; G01T 1/24; H01L 27/00; H01L 21/44

(52) U.S. Cl. 361/56; 250/370.01; 257/529; 257/530; 438/600; 438/601; 257/E27.001

(57) ABSTRACT

In one exemplary embodiment, a detector of electromagnetic radiation includes: a substrate; at least one layer of semiconductor material formed on the substrate, said at least one layer of semiconductor material defining a radiation absorbing and detecting region; an electrical contact configured to couple said region to a readout circuit; and a fuse coupled between the region and the electrical contact. In another exemplary embodiment, a fusible link between a first component and a second component is provided and includes: a fuse with an undercut located underneath at least a portion of the fuse; a first contact coupling the first component to the fuse; and a second contact coupling the second component to the fuse, wherein the undercut is disposed between the first contact and the second contact. In another exemplary embodiment, a fusible link includes a fuse having a layer of material having a negative temperature coefficient of resistance.

### TECHNICAL FIELD

These teachings relate generally to the protection of individual circuit elements where other circuit components are biased or are otherwise operated at voltages that exceed the breakdown voltage of the other circuit elements.

### BACKGROUND

A problem arises during the heterogeneous integration of transducers, sensors or other components that must operate at high voltages relative to the breakdown voltage of integrated circuit (IC) components, such as those found in Very Large Scale Integration (VLSI) embodiments. The integration of such components becomes an issue when attempting to preserve circuit operability after the occurrence of a catastrophic failure of a high voltage component. This problem has been compounded by the evolutionary reduction in the operating and breakdown voltages of VLSI circuits as efforts continue to reduce the scale of these circuits to smaller geometries. For example, the next generation of 0.13 micron VLSI circuits are expected to operate at approximately 1 to 2 volts, and the breakdown or damage voltage threshold of these circuits is expected to be approximately 10 volts. However, many sensors, piezoelectric devices, micro-electromechanical (MEM) devices, avalanche photodiodes and other components require operating voltages well above the VLSI circuit damage threshold. In a typical circuit, the number of such higher voltage components may exceed one thousand. This results in a significant probability that at least one of these components will experience a catastrophic failure. For example, a single component within a circuit (e.g. a transducer) may short, thus improperly directing its bias voltage and destroying the associated VLSI circuit as a result.

It is known in the art to provide integrated circuits with fuses fabricated from aluminum or polysilicon for protection from catastrophic component failures. These materials are compatible with integrated circuit fabrication processes, and fuses fabricated from these materials are designed to open upon application of over 100 mA of instantaneous current. A current of this magnitude may be generated unexpectedly by an EMI pulse, or by other similar events. However, catastrophic failures of modern VLSI circuits may occur at thresholds that are significantly less than those associated with 100 mA current spikes.

One solution would be to incorporate zener diodes within the circuits as protection elements. However, the large forward current incurred when a transducer is shorted can add crosstalk and noise to the circuit that would not be affected by the presence of zener diodes. Also, for large circuit arrays the power dissipation can be significant, even though only a few components may have shorted. For example, in an array of 1,000 avalanche photodiodes with 1% (10) shorted elements biased at 100 volts through a, 10 kOhm load resistor, an additional, and significant, 10 Watts of circuit power would be dissipated.

Another problem with this approach is that current limiting in and of itself does not prevent the high voltage from reaching the sensitive components of the integrated circuit.

### SUMMARY

In one exemplary aspect of the invention, a detector of electromagnetic radiation includes: a substrate; at least one layer of semiconductor material formed on the substrate, wherein said at least one layer of semiconductor material defines a radiation absorbing and detecting region; an electrical contact configured to couple said region to a readout circuit; and a fuse coupled between the region and the electrical contact.

In a further exemplary aspect of the invention, a fusible link between a first component and a second component is provided. The fusible link comprises: a fuse with an undercut located underneath at least a portion of the fuse; a first contact coupling the first component to the fuse; and a second contact coupling the second component to the fuse, wherein the undercut is disposed between the first contact and the second contact.

In a further exemplary aspect of the invention, a method is provided. The method is for protecting an integrated circuit from damage to the integrated circuit by a failure of a circuit component that is coupled to the integrated circuit and includes: coupling a first contact region to the circuit component; coupling a second contact region to the integrated circuit; fabricating a fuse, wherein the fuse extends from the first contact region to the second contact region; and providing an undercut located underneath at least a portion of the fuse.

In another exemplary aspect of the invention, a fusible link between a first component and a second component is provided. The fusible link comprises: a fuse comprising a layer of material having a negative temperature coefficient of resistance; a first contact coupling the first component to the fuse; and a second contact coupling the second component to the fuse. Said fusible link may be placed in an array coincident with one or more circuit elements that are to be protected.

In a further exemplary aspect of the invention, a method is provided. The method is for protecting an integrated circuit from damage to the integrated circuit by a failure of a circuit component that is coupled to the integrated circuit and includes: fabricating a fuse comprising a layer of material having a negative temperature coefficient of resistance; coupling a first contact of the fuse to the circuit component; and coupling a second contact of the fuse to the integrated circuit.

### BRIEF DESCRIPTION OF THE DRAWINGS

The foregoing and other aspects of these teachings are made more evident in the following Detailed Description of the Preferred Embodiments, when read in conjunction with the attached Drawing Figures, wherein:

FIG. 1A is an enlarged elevational view, not to scale, showing an array of radiation detector photodiode pixels connected to a readout integrated circuit (ROIC);

FIG. 1B is an enlarged cross-sectional view of a portion of the array of integrated photodiodes, and shows a fusible resistive link incorporated into each pixel;

FIG. 1C shows an equivalent electrical schematic diagram of one of the pixels depicted in FIG. 1B;

FIG. 2A shows an enlarged cross-sectional view of an exemplary fusible link;

FIG. 2B shows a top view of the exemplary fusible link shown in FIG. 2A;

FIG. 2C is an enlarged cross-sectional view illustrating a neck-down design of an exemplary fusible link with thermal shunts;

FIG. 2D is an enlarged cross-sectional view of an exemplary embodiment of the fusible link disposed between an indium bump and a circuit via for connecting to a readout integrated circuit (ROIC);

FIG. 3 is a graphical depiction that compares fuse performance for fuses formed of materials with differing temperature coefficients of resistance (TCR), where power dissipation is measured as a function of voltage, wherein FIG. 3A illustrates the power dissipation for fuses formed of negative TCR materials, FIG. 3B illustrates the power dissipation for fuses formed of neutral TCR materials, and FIG. 3C illustrates the power dissipation for fuses formed of positive TCR materials;

FIG. 4 depicts a flowchart illustrating one non-limiting example of a method for practicing the exemplary embodiments of this invention;

FIG. 5 shows an enlarged cross-sectional view of an exemplary fusible link disposed between an indium bump and a circuit via for connecting to a ROIC, with an undercut located underneath a portion of the fusible link;

FIG. 6 depicts an exemplary array of radiation detector photodiodes, each having a fusible link with an undercut;

FIG. 7 illustrates a close up view of one photodiode of the exemplary array of FIG. 6;

FIG. 8 depicts an exemplary broken fusible link;

FIG. 9A shows an exemplary unbroken fusible link;

FIG. 9B shows the exemplary fusible link in FIG. 9A after it has been broken by a fusing current;

FIG. 10 shows a graph of current vs. voltage for exemplary fusible links with an undercut;

FIG. 11 depicts a flowchart illustrating another non-limiting example of a method for practicing the exemplary embodiments of this invention;

FIG. 12 depicts a flowchart illustrating another non-limiting example of a method for practicing the exemplary embodiments of this invention; and

FIG. 13 depicts a flowchart illustrating another non-limiting example of a method for practicing the exemplary embodiments of this invention.

### DETAILED DESCRIPTION

In accordance with the teachings of this invention it becomes possible to maintain as much of the functionality of a circuit as possible after a failure of one or a few components, and to have the failed component(s) automatically disconnect from the circuit when some predetermined value of DC current is exceeded. In one exemplary embodiment, the value of the DC current may be, as an example, in the 0.1 mA to 10 mA range. Note that other values may be utilized as warranted by detector or circuit requirements. To accomplish this goal, the invention employs a fusible link that is compatible with the integrated circuit and the transducer component. The fusible link has a small geometric size (for example, in the range of about 5-50 square microns), and is capable of fusing (opening) at low currents (for example, in the 0.1 mA to 10 mA range). The use of this invention enables the automatic disconnection of a shorted component from a circuit, for example, where the shorted component operates at a voltage that is greater than the breakdown voltage of an associated integrated circuit.

As employed herein a reference to a shorted component is made to one that conducts an abnormally large current (for that component), and it does not necessarily imply that a substantially zero ohm path exists for current through the component. In general, a shorted component will be one that conducts a sufficient amount of current to activate and open the fusible link that is provided in accordance with this invention.

The presently preferred embodiment of the fusible link provides both a load resistance and a mechanism for disconnecting the shorted component. The small size of the fusible link is compatible with a variety of components that may be attached to or interfaced with an integrated circuit, and that operate at a voltage that is higher than the breakdown voltage of the integrated circuit.

For purposes of illustration the fusible link may be implemented within, for example, an avalanche photodiode (APD) or p-intrinsic-n (PIN) photodiode pixel as a part of a focal plane array (FPA) of electromagnetic radiation detectors. In this case, the photodetectors may be considered as transducing incident electromagnetic radiation into a detectable electrical signal, and an attached readout integrated circuit is to be protected from the typically higher bias voltage(s) used to bias the detectors. In one non-limiting, exemplary embodiment of this invention, a semi-metal, such as VOx, is used as the fusible link. VOx offers an inherent combination of high resistivity and negative temperature coefficient of resistance (TCR). Accordingly, the use of the VOx material, or a material with similar characteristics, enables efficient and fast fuse protection at relatively low currents, as compared to conventional Al integrated circuit fuses, while providing for a fuse size that can be accommodated within a practical circuit design. Upon failure of the transducer, the fusible link melts and opens, thereby disconnecting the transducer. In this exemplary embodiment, the fuse is coupled in series between a photodiode and an input to the readout integrated circuit, often an amplifier.

In this exemplary embodiment, the fusible link measures between, for example, about 5 microns to about 50 microns on a side. The load resistance for the transducer ranges between, for example, about 20 kOhm and about 100 kOhm. The resultant fusing is reproducible and occurs between, for example, about 0.1 mA and about 10 mA

In other exemplary embodiments of this invention, the fuse may be made from a neutral TCR material or from a positive TCR material.

For example, in one preferred non-limiting, exemplary embodiment, a metal or two-component metal, such as NiCr, is utilized in conjunction with an undercut to thermally isolate a region in air or vacuum. Said region of the fuse will preferentially melt when subjected to a sufficiently high current, the level of which may be determined by the geometry and thickness of the fuse and undercut regions.

As a non-limiting example, a detector of electromagnetic radiation (e.g., a photodetector array) may include a fuse in accordance with this exemplary embodiment coupled between the radiation detecting region and the electrical contact, where the fuse comprises a layer of NiCr that is disposed between thermal shunts. The thermal shunts can be comprised of a layer of TiNi. As a further example, a readout circuit may include a fuse coupled between an Indium bump (i.e., that may be coupled to a detector of electromagnetic radiation, e.g., by hybridization) and a via to the readout circuit, and may function as a load resistance. In a preferred non-limiting, exemplary embodiment, the layer of NiCr may have a substantially constant thickness and a variable width defining a neck-down region wherein fusing occurs upon an occurrence of a current flow that exceeds a fusing threshold. A low resistance can be obtained by use of an undercut to reduce the fusing threshold.

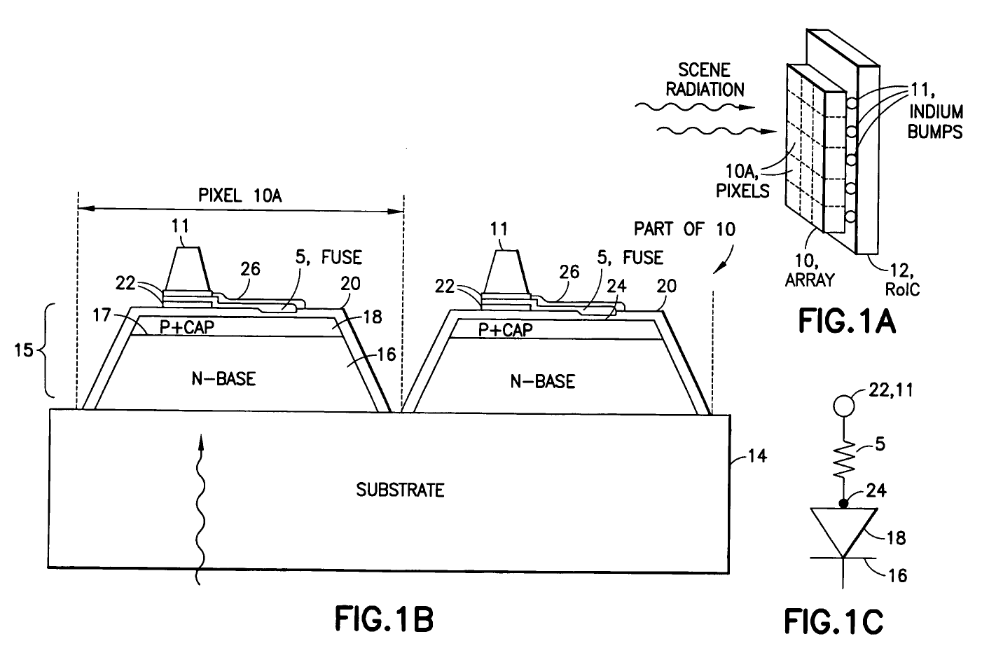

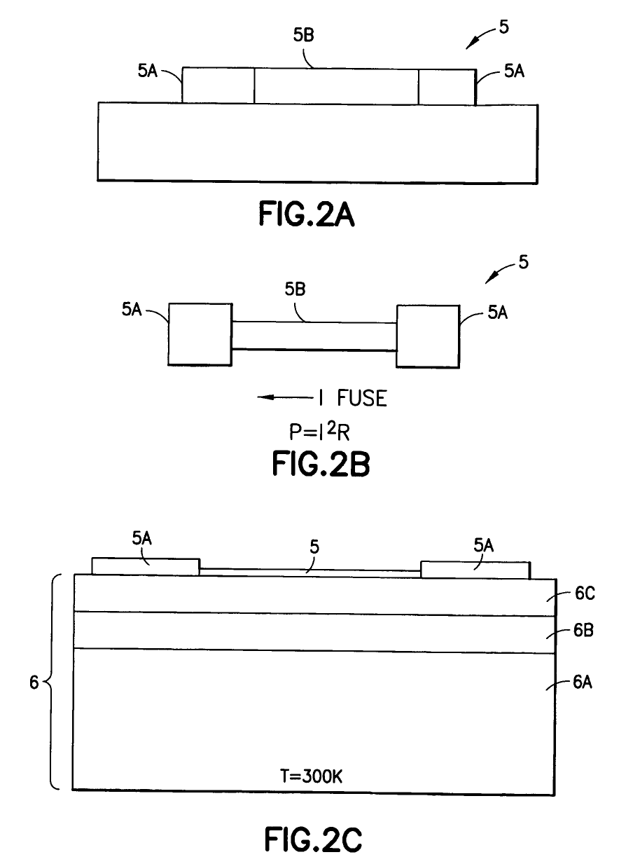

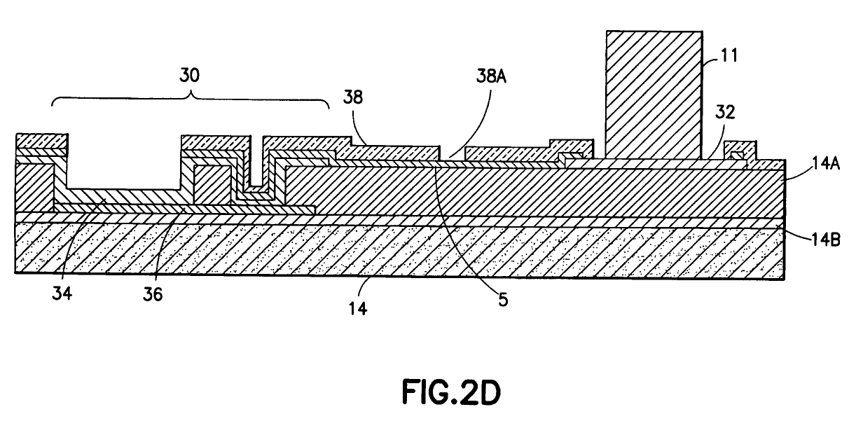

Referring to FIG. 1A, for purposes of illustration, exemplary fusible links are implemented within an array 10 of pixels 10A containing avalanche photodiodes (APD) designed for high speed operation. The array 10 is connected to a readout integrated circuit (ROIC) 12, such as a silicon-based ROIC, using, for example, conventional Indium bump technology. Individual ones of the pixels 10A contain a fusible link or fuse 5 constructed from negative, neutral or positive TCR material, as can be seen in FIGS. 2A and 2B. The material selected for use in the fusible links is presently preferred to be a bimetal such as NiCr having a characteristic resistance that can be adjusted to relatively high values (of the order of 0.1K to 100K per square). Efficient and fast fusing at relatively low currents occurs through the use of this material, or another compatible material that can be combined with an undercut region to facilitate efficient and uniform fusing.

Although a bimetal, such as NiCr, is presently preferred, the exemplary embodiments of the invention are not limited solely to use thereof. In other embodiments, other bimetals may be utilized. In further embodiments, a semimetal, such as VOx, may be used. In other embodiments, Ti, Ti-based compounds (e.g., TiN) or other compounds may be utilized.

For the purposes of this invention, a semi-metal is an element or an alloy exhibiting certain properties of metals and certain properties of non-metals. Semi-metals are normally opaque with a metallic luster, and combine with other elements to form minerals as metals do. In all other significant aspects they act like non-metals. Vanadium oxide (VOx) is one example of a suitable semi-metal.

Also for the purposes of this invention, a negative TCR implies that as temperature increases the electrical resistance decreases.

Other materials which may be deposited in uniform thin layers and have suitably high resistance per unit length include other bimetals (e.g., TiNi), metallic compounds (e.g., TiN, MoN) and single component metals (e.g., Mo, Ti, Ni).

FIG. 1B illustrates one exemplary embodiment of the fuse 5 with an avalanche photodiode or PIN detector pixel 10A as a part of the focal plane array 10. Here the fuse 5 is fabricated as part of the detector array process. Briefly, each pixel 10A rests on a substantially transparent (at the wavelength or wavelengths of interest) substrate 14 and is formed as a mesa structure 15 containing an n-type base layer 16 and a p+ cap layer 18. The interface between the n-type base 16 and a p+ cap 18 forms a p-n junction 17. The n-type base layer 16 and the p+ cap layer 18 can be formed of any suitable type of semiconductor material, depending on the wavelength range or ranges of interest, and may be comprised of Silicon, or a Group II-VI material such as HgCdTe or CdS, or a Group III-V material such as GaAs or InGaAs. Any suitable and appropriate types of dopant or dopants may be employed as well. Any suitable photodiode, photoconductive or rectifying detector can be utilized, particularly as integrated circuit elements are reduced. Alternative cap and base layers may be utilized, such as N+ cap, P base or complex multilayer structures (e.g., Quantum Well or Superlattice type photodiodes, MIM or Schottky detectors), as non-limiting examples.

In accordance with an aspect of the teachings of this invention, the mesas 15 are coated with a dielectric layer 20 having a dual function of a passivation layer and high voltage insulation layer. The indium bump 11 is electrically coupled to the fuse 5 through a single or a dual metal system 22 to promote adhesion of the indium bump 11 and to provide a low noise electrical contact to the fuse 5 and to the photodiode. In the illustrated embodiment, the metal system 22 is comprised of a first or bottom layer that is disposed on the dielectric layer 20, and a second or top layer upon which the indium bump 11 is formed. Between the top and bottom layers of the metal system 22 is disposed one end of the fuse 5. The opposite end of the fuse 5 is electrically connected to the p+ cap layer 18 through a dual metal system contact 24. Also shown is an optional dielectric layer 26 that is disposed in a protective manner over the fuse 5.

FIG. 1C shows an equivalent electrical schematic diagram, and illustrates the exemplary fuse 5, depicted as a resistance, that connects the photodiode of the pixel 10A to the indium bump 11, and thus connects the p-n junction 17 of the photodiode to the ROIC 12 shown in FIG. 1A.

In this exemplary embodiment, an offset contact for the photodiode is preferred in order to provide room for the fusible link 5. This is indicated by the indium bump 11 being located away from the center of the mesa structure 15.

In this exemplary embodiment, the fusible link 5 is preferably formed of NiCr or another thin film bimetal, a single component metal or a semi-metal. The fusible link 5 is located between the two insulating layers (20 and 26) and electrically interconnects the indium bump 11 (the ROIC 12 contact) and the p+ cap layer 18 of the photodiode.

This approach is suited for, but not limited to use with, an array of photodiodes that may be PN diodes, PIN diodes, conventional avalanche photodiodes (APDs) and Separate Absorption and Multiplication (SAM) APDs. This approach is also suited for, but not limited to use with, other detector types such as Superlattice, MQW and MIM, Schottky or photoconductive detectors that are hybridized or wire-bonded to a standard ROIC 12. In the illustrated example, the photodiode is formed using a mesa etch to provide physical isolation between pixels 10A thereby minimizing optical cross talk. The use of the mesa etch also tends to reduce breakdown while achieving a high packing density. However, the use of this invention is consistent with many other configurations of other photodiodes such as planar diodes, non-photovoltaic detectors, and with other transducers (e.g., piezoelectric and MEMs) that require a relatively high operating voltage as compared to an associated integrated circuit. In the illustrated example, the array 10 may operate with a bias voltage of about 100 VDC, wile the ROIC 12 may operate with conventional logic levels of 5 VDC or less.

In the dielectric layer 20, in addition to the use of what may be a conventional passivation coating to reduce surface states, it is preferred to employ an insulating overcoat of a dielectric material, such as Si₃N₄, that is applied to prevent the high voltage from propagating by some path other than through the fuse 5. As such, the layer 20 may actually be a dual layer, with an inner passivation coating layer applied to the semiconductor material of the n-type and p-type layers 16 and 18, and an outer dielectric coating layer that inhibits leakage around the fuse 5.

The metallization 24 is preferably a thin contact metal or metals that are deposited and delineated to cover an exposed area of the p+ cap layer 18 of the photodiode. The contact metal(s), which may be, for example, Au:NiCr, have the property of providing an ohmic contact to the p+ layer 18 and at the same time a low noise contact to the NiCr or VOx material of the fuse 5.

Referring also to FIGS. 2A and 2B, the exemplary fuse 5 may be shaped like a “dog bone” with pads or thermal shunts 5A in the area of the contact to the p+ layer 18 and to the metal 22 beneath the indium bump 11, and a connecting strip 5B. One set of the pads 5A serve to provide an array of contacts on the top of the mesa structures 15 for an array of indium bumps 11 that are deposited and delineated on top of the Si₃N₄ insulator. The contact metals 22 are applied as needed to promote adhesion of the indium bump 11 to the insulator layer 20. Non-limiting examples of suitable adhesion-promoting metals include TiN and NiCr. The preferred metal system also provides a low noise contact to the underlying fuse 5 which may be fabricated from a bimetal (e.g., NiCr), a single component metal (e.g., Ni or Ti) or a semimetal (e.g., VOx).

The example shown in FIGS. 2A and 2B depicts a fuse having a width in the range of about 1-20 microns and a length in the range of about 1-20 microns. A suitable thickness is about 500 Angstroms. The actual dimensions are dependent on the resistivity of the material used in the fusible link 5. Typically, about one square of VOx having a thickness of 500 Angstroms provides 20,000 ohm of resistance, which is considered reasonable for a series resistance, and capable of fusing at low mA currents (e.g., less than about 10 mA). Alternate metal systems, such as one that utilizes NiCr with an undercut, may provide 1-5 kOhm of resistance and are compatible with low current (e.g., about 1 mA) fusing.

In addition to fabrication of the fuse on the detector array as illustrated in FIG. 1C, the fuse may be fabricated on other components or arrays, such as a silicon (or other semiconductor) ROIC, as a non-limiting example.

In this implementation, it was found that in a planar exemplary embodiment the fusing current may vary from about 1.25 to about 2.4 mA, the DC resistance may vary from about 2.1 to about 470 kOhms, the fusing voltage may vary from about 4.3 to about 6.4 volts, and the fusing power (W) may vary from about 8 mW to about 11.5 mW. These various figures are exemplary, and not limiting.

FIG. 2C shows a case of a neck-down exemplary embodiment of the fuse 5 with thermal shunts 5A. In this exemplary embodiment, the fuse 5 is comprised of a layer of NiCr and has a thickness of about 80 Angstroms, and the thermal shunts 5A are comprised of TiNi and have a thickness of about 500 Angstroms. NiCr is a material that exhibits a positive TCR. The thermal conductivity of TiNi is about 10 W/m-K, while the thermal conductivity of NiCr is about 91 W/m-K. This exemplary embodiment assumes, by way of example and not of limitation, a substrate system 6 containing a 700 micron thick Si substrate 6A capped with a one micron thick layer of SiN 6B and a 1.5 micron thick layer of SiO₂ 6C.

Reference is also made to FIG. 2D, which shows in greater detail the connectivity and structure of the fuse 5 in a non-planar exemplary embodiment. In this exemplary embodiment, the fuse 5 is comprised of NiCr and is disposed between the indium bump 11 and a via 30. The via 30 is assumed in this example to allow connectivity with the ROIC 12 (not shown). FIG. 2D clearly shows how the fuse 5 can be used with the non-planar surface geometries of integrated circuits.

As shown in FIG. 2D, in this exemplary embodiment, a TiNi layer 32 underlies the indium bump 11, and the NiCr fuse 5 is coupled between the TiNi layer 32 and another TiNi layer 34 that lies above an Al layer 36 at the via 30. The TiNi forms a low-noise electrical contact to the fuse 5 on one end and to the Aluminum pad 36 (input to the readout circuit) on the other end. In this embodiment, the substrate 14 can be Si having one or more Si₃N₄ layers 14A, 14B disposed thereon. A layer 38 of insulating overglass can be provided over the fuse 5 and other structures and, if desired, an optional hole 38A can be made through the overglass 38 to expose the neck of the fuse 5.

The thermal shunts 5A are useful in limiting the exposure of surrounding circuitry to the heat generated by the fuse 5 during an overload condition (prior to the fuse 5 melting and opening). Referring again to FIG. 2C, the NiCr fuse 5 layer (NiCr has a melting temperature of approximately 2500° C.) may vary in thickness from about 50 Angstroms to about 500 Angstroms, while the TiNi thermal shunts 5A may vary in thickness from about 500 Angstroms to about 5000 Angstroms. Alternate metal systems may be used.

Referring again briefly to FIG. 2B, the exemplary fuse 5 comprises a neck-down design having a neck-down region 5B disposed between thermal shunts 5A. The fuse 5 preferably has a constant thickness of fuse material (e.g., NiCr) but a variable width. Fusing is thereby promoted in the neck-down region 5B. In one embodiment, the temperature in the neck-down region 5B was found by thermal modeling to be about 1200 K, and the temperature in the area of the thermal shunts 5A was found to be about 800 K.

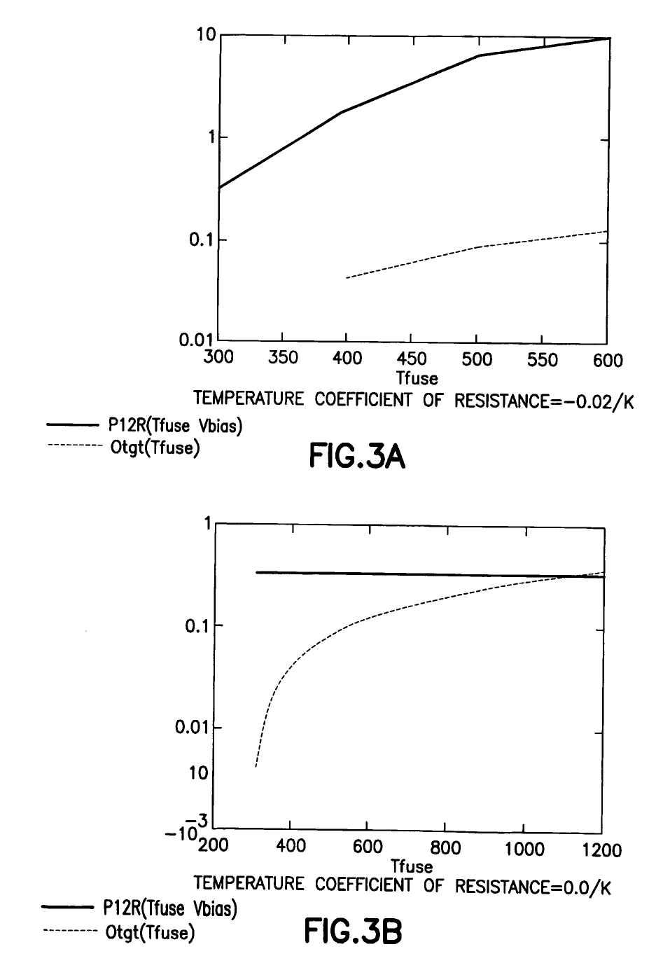

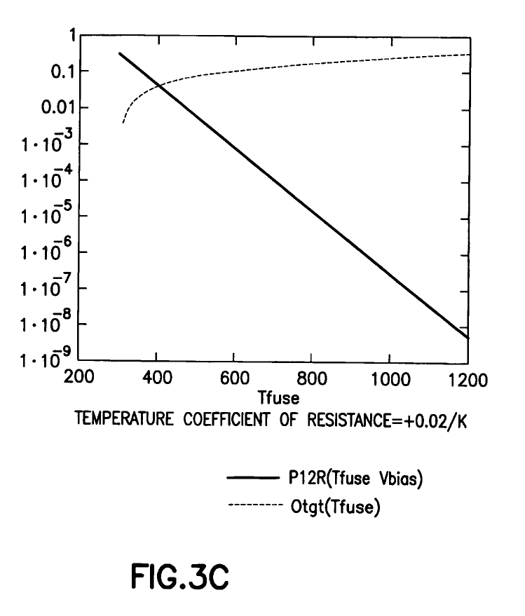

FIG. 3 presents a series of three graphs that compare fuse 5 performance as a function of the TCR of the fuse material, and clearly establish the advantage of a negative TCR, which in the case of VOx is approximately −02/K. More specifically, FIG. 3A is a graphical depiction of the power dissipation as a function of voltage for a fuse 5 formed of a material with a negative TCR (specifically, TCR=−0.02/K). FIG. 3B also shows power dissipation as a function of voltage, this graph being specific to fuses formed of materials with neutral TCR (TCR=0.0/K). FIG. 3C shows the same relationship for fuses formed of materials with a positive TCR (specifically TCR=0.02/K).

The three graphs presented in FIG. 3 illustrate that the highest power dissipation, in comparison with thermal power conduction, occurs in fuses formed of materials with negative TCR, such as VOx. This is due to the thermal runaway properties of such materials. Note that at 100 volts bias, a 300K resistance of 30 kOhms and a low thermal conductivity insulator is assumed to surround the resistor. Note as well in FIG. 3A that there is no equilibrium intersection above 300K, as in the graphs of FIGS. 3B and 3C.

During fabrication of the embodiment shown in FIG. 1B, and by example, conventional semiconductor layer growth and mesa etching steps can be followed. In a preferred embodiment the surfaces of the mesas 15 are passivated and then the optional high voltage coating is applied, thereby forming the coating layer 20. A window is then opened through the coating 20 to expose the p+ cap layer 18, and the metal contact layer 24 photolithographically defined and deposited, as is the lower layer of the contact 22. Next a mask is applied and the fuse 5 is deposited, such as by a reactive sputtering technique that applies VOx to a thickness of about 500 Angstroms. The fuse-defining mask is removed, and the upper layer of the metal system 22 is photolithographically defined and deposited, such as by sputtering. The dielectric coating 26 over the fuse 5 is then applied, followed by the application, in a conventional manner, of the indium bump 11 onto the upper layer of the metal system 22. During subsequent processing the array 10 is hybridized with the ROIC 12.

During fabrication of the exemplary embodiment shown in FIG. 2D, and by example, conventional semiconductor circuit fabrication can be utilized. In a preferred non-limiting, exemplary embodiment, a dielectric coating oxide or nitride is applied and an optional planar surface is obtained utilizing chemical mechanical polishing. A via or via array is then opened through the dielectric coating to expose the Aluminum pad layer 36 input to the readout integrated circuit. A TiNi metal contact layer 34 is photolithographically defined and deposited, as is the lower layer 32 of the contact to the Indium Bump 11. Next a mask is applied and the fuse 5 is deposited, such as by a reactive sputtering technique that applies NiCr to a thickness of about 500 Angstroms. The fuse-defining mask is subsequently removed. An optional dielectric coating 38 over the fuse 5 is then applied, followed by the application, in a conventional manner, of the indium bump 11 onto the upper layer of the metal system TiNi pad 32. During subsequent processing, the readout array 10 is hybridized, utilizing the Indium bump interconnect, to a detector array patterned with mating Indium bumps but without fuses.

While described above partly in the context of a fuse material such as NiCr, for the fuse 5, it can be appreciated that in other exemplary embodiments of this invention negative, neutral or positive temperature coefficient of resistance materials could be used to fabricate the fuse 5. For example, and as was stated above, VOx exhibits a negative TCR.

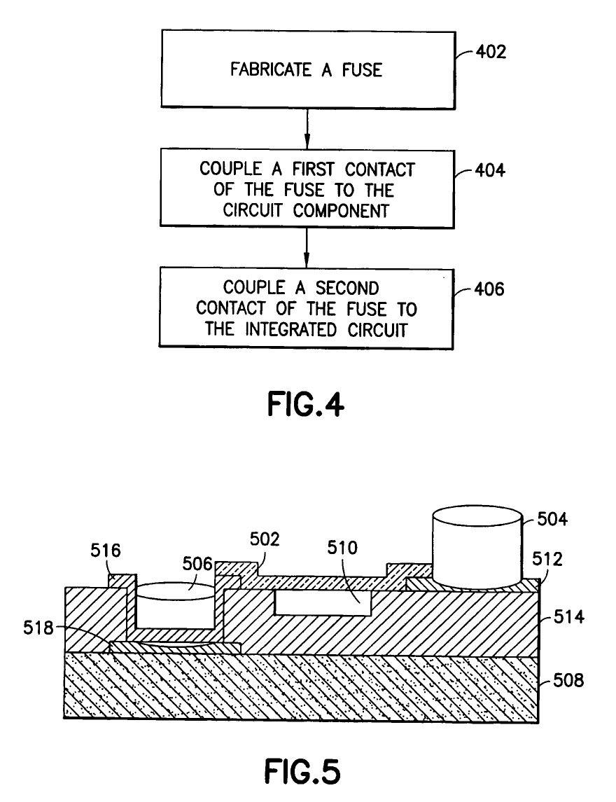

FIG. 4 depicts a flowchart illustrating one non-limiting example of a method for practicing the exemplary embodiments of this invention. The method is for protecting an integrated circuit from damage to the integrated circuit by a failure of a circuit component that is coupled to the integrated circuit and includes the following steps. In box 402, a fuse is fabricated. The fuse includes a layer of thin film material with suitable electrical resistance and thermal properties having a negative, positive or neutral temperature coefficient of resistance. In box 404, a first contact of the fuse is coupled to the circuit component. In box 406, a second contact of the fuse is coupled to the integrated circuit.

In other embodiments, the circuit component comprises a transducer. In further embodiments the fuse is fabricated during the fabrication of an array of photodetectors. In other embodiments, the material comprises a semi-metal material. In further embodiments, the material comprises VOx. In other embodiments, the method further comprises depositing an insulating overcoat that covers at least a portion of the fuse. In further embodiments, the first contact comprises one of Au:NiCr, TiN, or NiCr. In other embodiments, the fuse is characterized by a size in a range from about 5 to about 50 square microns. In further embodiments, a current in the range of about 0.1 mA to about 10 mA causes the fuse to open. In other embodiments, the method further comprises providing an undercut located underneath at least a portion of the fuse, as further explained below.

In other exemplary embodiments, an undercut (that is, a gap or pit) is employed in conjunction with the fuse. The undercut is located underneath at least a portion of the fuse and facilitates opening of the fuse in the region of the undercut. When the fuse breaks or melts, as explained above, the broken or molten portion of the fuse falls into the undercut. This increases the distance between the connected portions of the broken fuse (such as the portion coupled to a first component and the portion coupled to a second component, for example). The increased distance helps prevent after-pulsing (pulsing that can occur after the fuse breaks). FIGS. 5-10 illustrate various details of this feature. The undercut may also be employed in conjunction with the exemplary embodiments described above.

Referring to FIG. 5, there is shown an enlarged cross-sectional view of an exemplary fusible link 502 disposed between an indium bump 504 and a circuit via 506 for connecting to a ROIC 508, with an undercut 510 located underneath a portion of the fusible link 502. The indium bump 504 sits on a first contact metal 512. The fusible link 502 is coupled to the first contact metal 512 and extends along the top of the overglass 514, coupling to a second contact metal 516. The second contact metal 516 forms an area in the overglass 514 for a circuit via 506. There is also a top metal 518 coupling the second contact metal 516 to the input circuits of the readout integrated circuit array, ROIC 508. The indium bump 504 enables mating with a detector during hybridization.

Should the fusible link 502 of FIG. 5 break, due to reaching a threshold voltage or current, for example, the undercut 510 allows a portion of the broken fuse to fall into the undercut 510. This provides an increased distance between the other remaining portions of the broken fuse that are still coupled to the first contact metal 512 and the second contact metal 516. The increased distance helps prevent after pulsing.

The exemplary fusible link 502 may be formed as follows. Contact metal is deposited over the readout input via and over a location where the indium bump will sit. A trace of metal, the fusible link, is deposited between the two contact metal pads. A pit, the undercut, is etched, undercutting a portion of the fusible link, to suspend the fusible link over the undercut. Finally, the indium bump is placed on one of the contact metal pads to allow for mating with a detector during hybridization. Through these steps, conventional photolithography and deposition techniques may be employed, as known in the art.

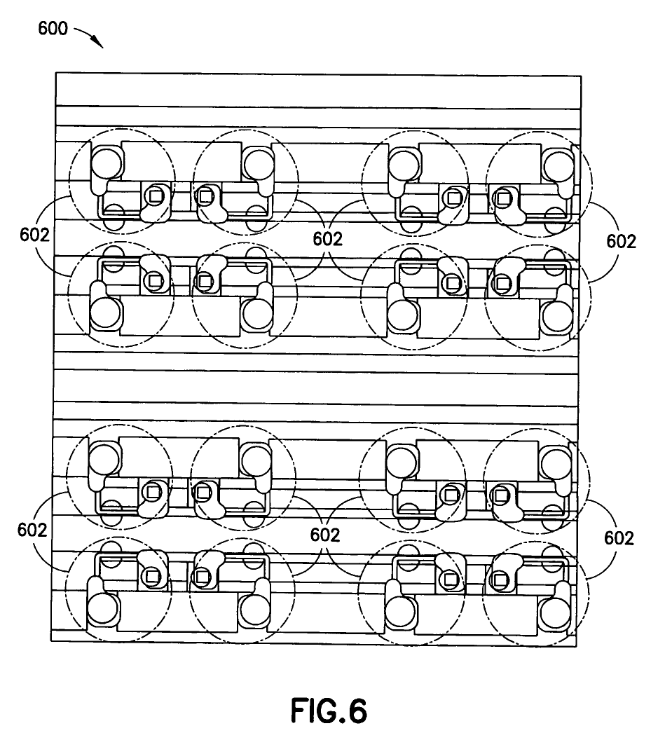

Referring to FIG. 6, there is shown an exemplary array 600 of radiation detector photodiodes 602, each photodiode 602 having a fusible link with an undercut.

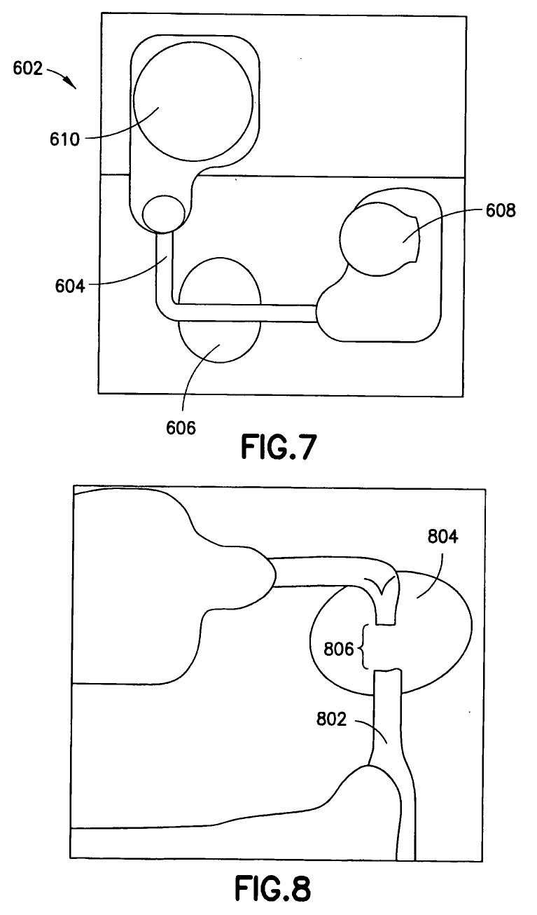

Referring also to FIG. 7, a close up view of one photodiode 602 of the exemplary array 600 of FIG. 6 is shown, with the fusible link 604, undercut 606, via 608 and indium bump 610 all plainly visible.

Referring to FIG. 8, there is shown an exemplary broken fusible link 802. The fusible link 802 has blown, due to a voltage or current above a threshold, for example, and a portion of the fusible link 802 has fallen into the undercut 804. Because a portion of the fusible link 802 has fallen into the undercut 804, there is an increased distance 806 between the remaining two ends of the fusible link 802.

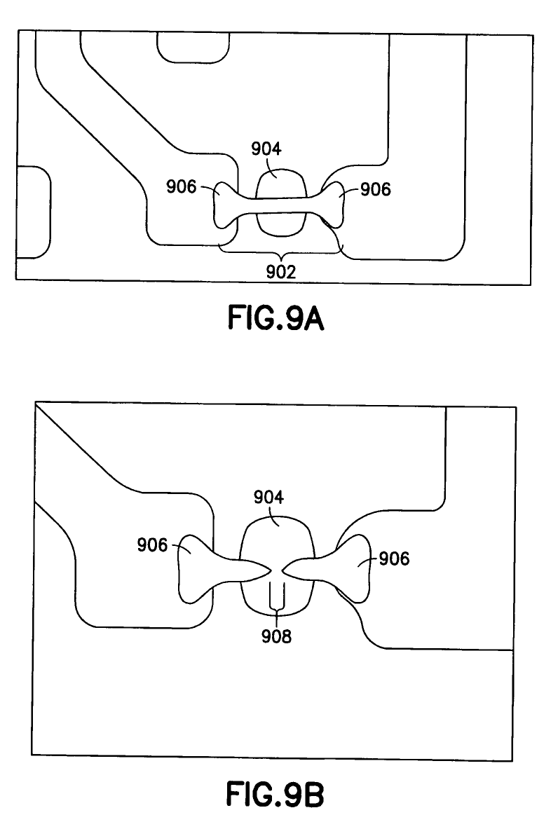

Referring to FIG. 9A, a presently preferred, exemplary NiCr fuse 902, with undercut 904, is shown. The fuse 902 comprises TiNi thermal shunts 906, as explained above.

Referring to FIG. 9B, the NiCr fuse 902 of FIG. 9A is shown after it has blown. As can be seen, and in accordance with aspects of the exemplary embodiments of the invention, a piece of the fuse 902 has fallen into the undercut 904 and, thus, there is now a gap 908 in the fuse. The undercut 904 enables efficient opening of the fuse 902 in the region of the undercut 904. Furthermore, the TiNi thermal shunts 906 prevent heat from reach the attached circuit of Indium bumps.

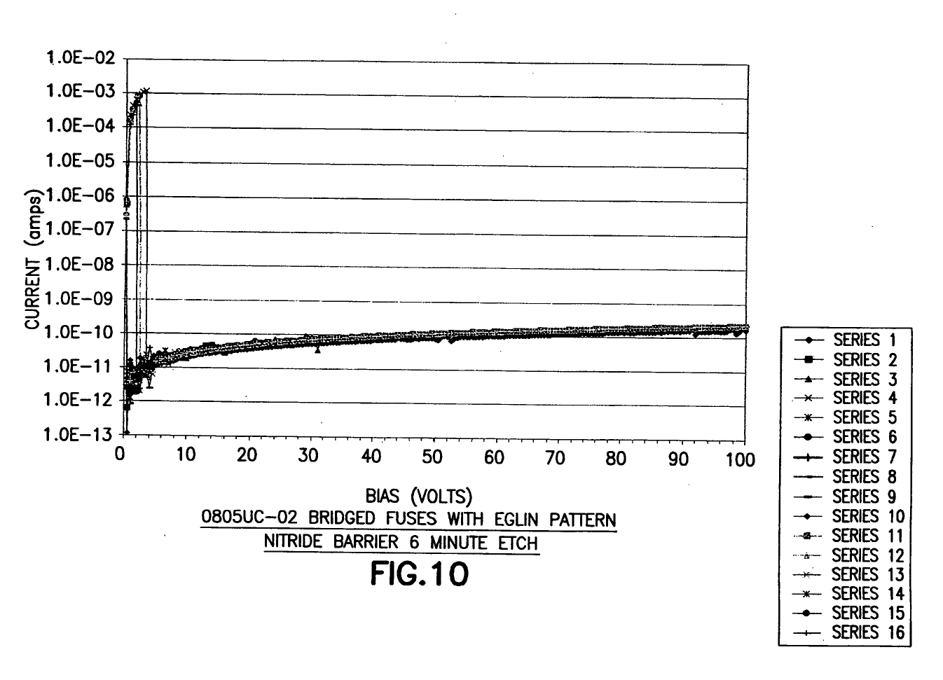

Referring to FIG. 10, a graph is shown of current vs. voltage for exemplary fusible links with an undercut. The exemplary fusible links blow (that is, break) around 1 mA of current at around 3 V. As the bias voltage is subsequently increased, there is no significant arcing at the tested voltages, even at voltages from 50-100 V. Very low residual conduction is observed even at higher voltages (e.g., the highest voltages).

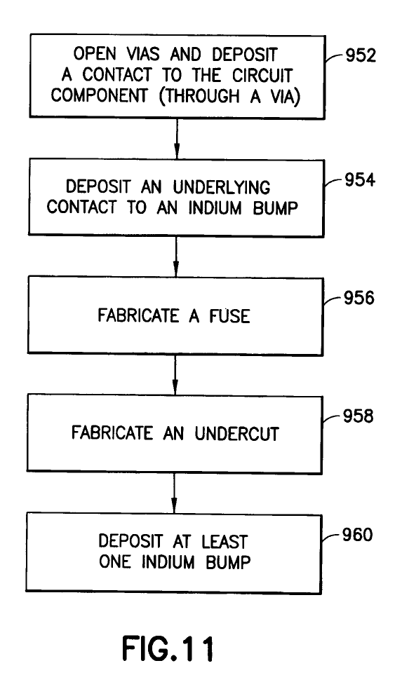

FIG. 11 depicts a flowchart illustrating another non-limiting example of a method for practicing the exemplary embodiments of this invention. The method is for protecting an integrated circuit from damage to the integrated circuit by a failure of a circuit component that is coupled to the integrated circuit and includes the following steps. In box 952, vias are opened and a contact to the circuit component (through a via) is deposited. In box 954, an underlying contact to an Indium bump is deposited. In box 956, a fuse is fabricated. In box 958, an undercut, located underneath at least a portion of the fuse, is fabricated. In box 960, at least one Indium bump is deposited.

In other embodiments, the circuit component comprises a transducer. In further embodiments the fuse is fabricated during the fabrication of an array of photodetectors. In other embodiments, the material comprises a semi-metal material. In further embodiments, the material comprises VOx. In other embodiments, the method further comprises depositing an insulating overcoat that covers at least a portion of the fuse. In further embodiments, the first contact comprises one of Au:NiCr, TiN, or NiCr. In other embodiments, the fuse is characterized by a size in a range from about 5 to about 50 square microns. In further embodiments, a current in the range of about 0.1 mA to about 10 mA causes the fuse to open. In other embodiments, the method further comprises providing an undercut located underneath at least a portion of the fuse, as further explained below. In further embodiments, the fuse includes a layer of material having a negative temperature coefficient of resistance. In other embodiments, the fuse includes a layer of material having a neutral temperature coefficient of resistance. In further embodiments, the fuse includes a layer of material having a positive temperature coefficient of resistance.

Described below are further non-limiting, exemplary embodiments of the invention. While the exemplary embodiments may be separately numbered, said numbering is not limiting as some aspects of the exemplary embodiments may be suitable for use in conjunction with one or more other aspects.

(1) In one non-limiting exemplary embodiment, a fusible link between a first component and a second component, comprising: a fuse comprising a layer of material having a negative temperature coefficient of resistance; a first contact coupling the first component to the fuse; and a second contact coupling the second component to the fuse.

A fusible link as above, wherein the first component comprises a transducer. A fusible link as in any above, wherein the fuse is located within an array of photodetectors. A fusible link as in the previous, wherein the material comprises a semi-metal material. A fusible link as in the previous, wherein the material comprises at least one of VOx and NiCr. A fusible link as in any above, wherein the fuse has an insulating overcoat covering at least a portion of said fuse. A fusible link as in any above, wherein at least the first contact comprises one of Au:NiCr, TiN, or NiCr. A fusible link as in any above, wherein the fuse is characterized by a size in a range from about 5 to about 50 square microns. A fusible link as in any above, wherein a current in the range of about 0.1 mA to about 10 mA causes the fuse to open. A fusible link as in any above, further comprising an undercut located underneath at least a portion of the fuse. A fusible link as in any above, wherein the fuse comprises a load resistance having a high resistivity. A fusible link as in any above, wherein the material comprises at least one of a semi-metal material, vanadium oxide (VOx), and nickel chromium (NiCr). A fusible link as in any above, wherein the fusible link is located within one of a readout circuit, a detector of electromagnetic radiation or an array of photodetectors.

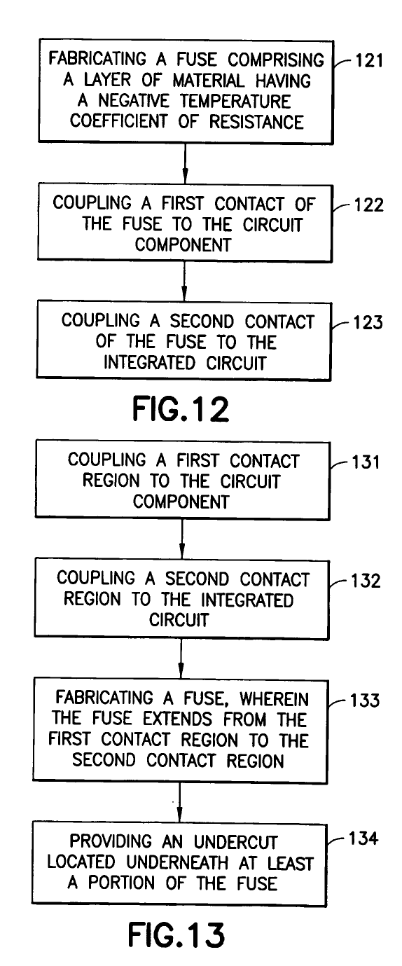

(2) In another exemplary embodiment, and as shown in FIG. 12, a method of protecting an integrated circuit from damage to said integrated circuit by a failure of a circuit component that is coupled to the integrated circuit, comprising: fabricating a fuse comprising a layer of material having a negative temperature coefficient of resistance (box 121); coupling a first contact of the fuse to the circuit component (box 122); and coupling a second contact of the fuse to the integrated circuit (box 123).

A method as above, wherein the circuit component comprises a transducer. A method as in any above, wherein the fuse is fabricated during the fabrication of an array of photodetectors. A method as in any above, wherein the fuse is fabricated one of on top of the integrated circuit or as part of an integrated circuit process. A method as in the previous, wherein the integrated circuit comprises a readout integrated circuit for a photodetector. A method as in any above, wherein the material comprises a semi-metal material. A method as in any above, wherein the material comprises at least one of VOx and NiCr. A method as in any above, further comprising depositing an insulating overcoat that covers at least a portion of the fuse. A method as in any above, wherein at least the first contact comprises one of Au:NiCr, TiN, or NiCr.

A method as in any above, wherein the fuse is characterized by a size in a range from about 5 to about 50 square microns. A method as in any above, wherein a current in the range of about 0.1 mA to about 10 mA causes the fuse to open. A method as in any above, further comprising providing an undercut located underneath at least a portion of the fuse. A method as in any above, wherein the integrated circuit comprises a component of a detector or a detector array. A method as in any above, wherein the material comprises at least one of a semi-metal material, vanadium oxide (VOx), and nickel chromium (NiCr). A method as in any above, wherein the integrated circuit comprises one of a readout circuit, a detector of electromagnetic radiation, a component of a detector of electromagnetic radiation or a component of an array of photodetectors.

(3) In another exemplary embodiment, a detector of electromagnetic radiation, comprising: a substrate; at least one layer of semiconductor material formed on the substrate, wherein said at least one layer of semiconductor material defines a radiation absorbing and detecting region; an electrical contact for coupling said region to a readout circuit; and a fuse coupled between the region and the electrical contact.

A detector as above, wherein the fuse comprises a negative temperature coefficient of resistance material. A detector as in any above, wherein the detector further comprises an undercut located underneath at least a portion of the fuse. A detector as in any above, where the fuse comprises a neutral temperature coefficient of resistance material. A detector as in any above, wherein the fuse comprises a positive temperature coefficient of resistance material. A detector as in any above, wherein the region comprises a first layer of semiconductor material and a second layer of semiconductor material forming a p-n junction with said first layer. A detector as in any above, wherein the p-n junction is contained within a mesa structure, and wherein the electrical contact comprises a metallic contact disposed over a top surface of said mesa structure.

A detector as in any above, wherein the fuse comprises one of a semimetal, a bimetal or a simple metal having suitable thermal and electrical properties. A detector as in any above, wherein the fuse has an insulating overcoat covering at least a portion of said fuse. A detector as in any above, wherein the fuse has a size in a range from about 5 to about 50 square microns. A detector as in any above, wherein a current in a range of about 0.1 mA to about 10 mA causes the fuse to open. A detector as in any above, wherein the fuse has a resistance in a range of about 1 kOhm to about 100 kOhm. A detector as in any above, wherein the fuse is coupled between an Indium bump and a top p+ cap layer of a photodiode.

(4) In another exemplary embodiment, a detector of electromagnetic radiation, comprising: a substrate; at least one layer of semiconductor material formed on the substrate, wherein said at least one layer of semiconductor material defines a radiation absorbing and detecting region; an electrical contact for coupling the region to a readout circuit; and a fuse coupled between the region and the electrical contact, the fuse comprising a layer of NiCr disposed between thermal shunts.

A detector as above, wherein the thermal shunts comprise a layer of TiNi. A detector as in any above, wherein the detector comprises a Silicon readout integrated circuit. A detector as in any above, wherein the fuse is coupled between an Indium bump and a via to the readout circuit. A detector as in any above, wherein the layer of NiCr on the Silicon Readout Integrated Circuit has a substantially constant thickness and a variable width defining a neck-down region wherein fusing occurs upon an occurrence of a current flow that exceeds a fusing threshold. A detector as in any above, wherein the layer of NiCr functions as a load resistance. A detector as in any above, further comprising an undercut located underneath at least a portion of the fuse.

(5) In another exemplary embodiment, a fusible link between a first component and a second component, comprising: a fuse with an undercut located underneath at least a portion of the fuse; a first contact coupling the first component to the fuse; and a second contact coupling the second component to the fuse, wherein the undercut is disposed between the first contact and the second contact.

A fusible link as above, wherein the fuse is located within an array of photodetectors. A fusible link as in any above, wherein the fuse is located one of within or on top of a Silicon readout integrated circuit configured to be bonded or hybridized to a mating detector array. A fusible link as in any above, wherein the fuse comprises a layer of semi-metal, bimetal or simple metal. A fusible link as in any above, wherein a current in the range of about 0.1 mA to about 10 mA causes the fuse to open. A fusible link as in any above, wherein the fusible link is located within one of a readout circuit, a detector of electromagnetic radiation or an array of photodetectors. A fusible link as in any above, wherein the first component comprises a first electrical component and the second component comprises a second electrical component.

(6) In another exemplary embodiment, and as illustrated in FIG. 13, a method of protecting an integrated circuit from damage to said integrated circuit by a failure of a circuit component that is coupled to the integrated circuit, comprising: coupling a first contact region to the circuit component (box 131); coupling a second contact region to the integrated circuit (box 132); fabricating a fuse, wherein the fuse extends from the first contact region to the second contact region (box 133); and providing an undercut located underneath at least a portion of the fuse (box 134).

A method as above, wherein the fuse comprises a layer of semi-metal, bimetal or simple metal. A method as in any above, wherein the fuse comprises a layer of material having a negative temperature coefficient of resistance. A method as in any above, wherein a current in the range of about 0.1 mA to about 10 mA causes the fuse to open. A method as in any above, wherein the fuse is fabricated one of on top of the integrated circuit or as part of the integrated circuit. A method as in any above, wherein the integrated circuit comprises one of a readout circuit, a detector of electromagnetic radiation, a component of a detector of electromagnetic radiation or a component of an array of photodetectors.

(7) In another exemplary embodiment, a detector of electromagnetic radiation, comprising: a substrate; at least one layer of semiconductor material formed on the substrate for defining a radiation absorbing and detecting region; an electrical contact for coupling said region to a readout circuit; and a fuse coupled between the region and the electrical contact, wherein an undercut is located underneath at least a portion of the fuse.

A detector as above, wherein the region comprises a first layer of semiconductor material and a second layer of semiconductor material forming a p-n junction with said first layer. A detector as in the previous, wherein the p-n junction is contained within a mesa structure, and wherein the electrical contact comprises a metallic contact disposed over a top surface of said mesa structure. A detector as in any above, wherein the fuse is coupled between an Indium bump and a p+ cap layer of a photodiode.

(8) In another exemplary embodiment, an array of radiation detectors comprising a plurality of individual detectors, each individual detector comprising: a substrate; at least one layer of semiconductor material formed on the substrate for defining a radiation absorbing and detecting region; an electrical contact for coupling said region to a readout circuit; and a load resistance coupled between the region and the electrical contact, wherein the load resistance is operable to form an open circuit at a certain threshold of load current.

An array as above, further comprising an undercut located underneath at least a portion of the load resistance. An array as in any above, wherein the load resistance comprises a negative temperature coefficient of resistance material.

(9) In another exemplary embodiment, an array of readout circuits comprising a plurality of individual circuits, each individual circuit comprising: a substrate; readout circuitry; an electrical contact for coupling said readout circuitry to another circuit; and a load resistance coupled between the readout circuitry and the electrical contact, wherein the load resistance is operable to form an open circuit at a certain threshold of load current.

An array as above, further comprising an undercut located underneath at least a portion of the load resistance. An array as in any above, wherein the load resistance comprises a negative temperature coefficient of resistance material. An array as in any above, wherein the array of readout circuits comprises a Silicon readout integrated circuit array configured to connect to another array. An array as in the previous, wherein the Silicon readout integrated circuit array is configured to connect to the other array by wirebonding or Indium bump hybridization, wherein the other array comprises a high voltage-biased detector array or a plurality of transducers.

(10) In another exemplary embodiment, a circuit comprising: a first substrate; a high voltage component coupled to the first substrate; a second substrate; a low voltage component coupled to the second substrate; an electrical connection path extending between the high voltage component and the low voltage component; and at least one thin film fuse disposed along a portion of the electrical connection path, wherein the at least one thin film fuse is configured to resistively couple the high voltage component and the low voltage component, wherein the at least one thin film fuse is configured to open at a current in the range of about 0.1 mA to about 10 mA.

A circuit as above, wherein the high voltage component comprises at least one detector or at least one piezoelectric transducer. A circuit as in any above, wherein the at least one thin film fuse comprises a material having one of a negative, positive or neutral temperature coefficient of resistance. A circuit as in any above, wherein the current at which the at least one thin film fuse opens is adjustable. A circuit as in any above, wherein the at least one thin film fuse comprises an array of thin film fuses. A circuit as in any above, wherein an undercut is located underneath at least a portion of the at least one thin film fuse. A circuit as in any above, wherein the at least one thin film fuse comprises a negative temperature coefficient of resistance material.

(11) In another exemplary embodiment, an electrical component comprising: an operational portion; a contact configured to electrically couple the electrical component to a second electrical component; and a fuse disposed between the operational portion and the contact, wherein an undercut is located underneath at least a portion of the fuse.

An electrical component as above, wherein the electrical component comprises one of a readout circuit or a detector of electromagnetic radiation. An electrical component as in any above, wherein the fuse comprises a layer of material having a negative temperature coefficient of resistance.

Generally, various exemplary embodiments of the invention can be implemented in different mediums, such as hardware, logic, special purpose circuits or any combination thereof.

Any use of the terms “connected,” “coupled” or variants thereof should be interpreted to indicate any such connection or coupling, direct or indirect, between the identified elements. As a non-limiting example, one or more intermediate elements may be present between the “coupled” elements. The connection or coupling between the identified elements may be, as non-limiting examples, physical, electrical, magnetic, logical or any suitable combination thereof in accordance with the described exemplary embodiments. As non-limiting examples, the connection or coupling may comprise one or more printed electrical connections, wires, cables, mediums or any suitable combination thereof.

The foregoing description has provided by way of exemplary and non-limiting examples a full and informative description of the best method and apparatus presently contemplated by the inventors for carrying out the invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention.

Furthermore, some of the features of the preferred embodiments of this invention could be used to advantage without the corresponding use of other features. As such, the foregoing description should be considered as merely illustrative of the principles of the invention, and not in limitation thereof.

What is claimed is:

1. A detector of electromagnetic radiation, comprising:
a substrate;
at least one layer of semiconductor material formed on the substrate, wherein said at least one layer of semiconductor material defines a radiation absorbing and detecting region;
an electrical contact configured to couple said region to a readout circuit; and
a fuse coupled between the region and the electrical contact.

2. A detector as in claim 1, wherein the fuse comprises a negative temperature coefficient of resistance material.

3. A detector as in claim 1, wherein the detector further comprises an undercut located underneath at least a portion of the fuse.

4. A detector as in claim 1, where the fuse comprises a neutral or positive temperature coefficient of resistance material.

5. A detector as in claim 1, wherein the region comprises a first layer of semiconductor material and a second layer of semiconductor material forming a p-n junction with said first layer.

6. A detector as in claim 1, wherein a current in a range of about 0.1 mA to about 10 mA causes the fuse to open.

7. A detector as in claim 1, wherein the detector comprises a photodiode in an array of photodiodes, wherein each photodiode in the array of photodiodes comprises an individual fuse coupled between a radiation and absorbing region and an electrical contact configured to couple said region to a readout circuit.

8. A fusible link between a first component and a second component, comprising:
a fuse with an undercut located underneath at least a portion of the fuse;
a first contact coupling the first component to the fuse; and
a second contact coupling the second component to the fuse, wherein the undercut is disposed between the first contact and the second contact.

9. A fusible link as in claim 8, wherein the fuse comprises a layer of semi-metal, bimetal or simple metal.

10. A fusible link as in claim 8, wherein a current in the range of about 0.1 mA to about 10 mA causes the fuse to open.

11. A fusible link as in claim 8, wherein the fusible link is located within one of a readout circuit, a detector of electromagnetic radiation or an array of photodetectors.

12. A fusible link as in claim 8, wherein the fusible link is located one of within or on top of a Silicon readout integrated circuit configured to be bonded or hybridized to a mating detector array.

13. A method of protecting an integrated circuit from damage to said integrated circuit by a failure of a circuit component that is coupled to the integrated circuit, comprising:
coupling a first contact region to the circuit component;
coupling a second contact region to the integrated circuit;
fabricating a fuse, wherein the fuse extends from the first contact region to the second contact region; and
providing an undercut located underneath at least a portion of the fuse.

14. A method as in claim 13, wherein the fuse comprises a layer of semi-metal, bimetal or simple metal.

15. A method as in claim 13, wherein a current in the range of about 0.1 mA to about 10 mA causes the fuse to open.

16. A method as in claim 13, wherein the fuse is fabricated one of on top of the integrated circuit or as part of the integrated circuit.

17. A method as in claim 13, wherein the integrated circuit comprises one of a readout circuit, a detector of electromagnetic radiation, a component of a detector of electromagnetic radiation or a component of an array of photodetectors.

18. A fusible link between a first electrical component and a second electrical component, comprising:
a fuse comprising a layer of material having a negative temperature coefficient of resistance;
a first contact coupling the first component to the fuse; and
a second contact coupling the second component to the fuse.

19. A fusible link as in claim 18, wherein a current in the range of about 0.1 mA to about 10 mA causes the fuse to open.

20. A fusible link as in claim 18, wherein the fusible link is located within one of a readout circuit, a detector of electromagnetic radiation or an array of photodetectors.

21. A fusible link as in claim 18, wherein an undercut is located underneath at least a portion of the fuse.

22. A method of protecting an integrated circuit from damage to said integrated circuit by a failure of a circuit component that is coupled to the integrated circuit, comprising:
fabricating a fuse comprising a layer of material having a negative temperature coefficient of resistance;
coupling a first contact of the fuse to the circuit component; and
coupling a second contact of the fuse to the integrated circuit.

23. A method as in claim 22, wherein a current in the range of about 0.1 mA to about 10 mA causes the fuse to open.

24. A method as in claim 22, wherein the integrated circuit comprises one of a readout circuit, a detector of electromagnetic radiation, a component of a detector of electromagnetic radiation or a component of an array of photodetectors.

25. A method as in claim 22, further comprising: providing an undercut located underneath at least a portion of the fuse.
